(19) United States
(12) Patent Application Publication
(10) Pub. No.: US 2020/0111725 A1
(43) Pub. Date: Apr. 9, 2020

(54) STACKED HEAT EXCHANGER AND METHOD FOR PRODUCING STACKED HEAT EXCHANGER

(71) Applicant: DENSO CORPORATION, Kariya-city (JP)

(72) Inventor: Ryohei TOMITA, Kariya-city (JP)

(21) Appl. No.: 16/704,312

(22) Filed: Dec. 5, 2019

Related U.S. Application Data
(63) Continuation of application No. PCT/JP2018/019168, filed on May 17, 2018.

(30) Foreign Application Priority Data
Jun. 9, 2017 (JP) 2017-114058
May 8, 2018 (JP) 2018-090096

(51) Int. Cl. H01L 23/473; B23P 15/26; F28D 7/16; H01L 25/18; H05K 7/20; H01L 21/48

(52) U.S. Cl. CPC H01L 23/473; B23P 15/26; F28D 7/1607; F28F 2275/04; H05K 7/20927; H01L 21/4882; F28F 2210/10; H01L 25/18

(57) ABSTRACT

A stacked heat exchanger includes a first passage tube and a second passage tube that are included in a plurality of passage tubes stacked in a stacking direction. The first passage tube has a first projecting pipe, and the second passage tube has a second projecting pipe. The second projecting pipe has a fitted portion fitted into an inner side of the first projecting pipe, and is connected to the first projecting pipe such that the refrigerant can flow therethrough. The first projecting pipe has a joined portion joined to the fitted portion on a radially outer side of the fitted portion. The joined portion has an outer circumferential surface and an end of the first projecting pipe. The outer circumferential surface of the joined portion extends in the stacking direction to the end along an outer circumferential surface of the fitted portion.

### CROSS REFERENCE TO RELATED APPLICATIONS

The present application is a continuation application of International Patent Application No. PCT/JP2018/019168 filed on May 17, 2018, which designated the U.S. and claims the benefit of priority from Japanese Patent Application No. 2017-114058 filed on Jun. 9, 2017, and Japanese Patent Application No. 2018-090096 filed on May 8, 2018. The entire disclosures of all of the above applications are incorporated herein by reference.

### TECHNICAL FIELD

The present disclosure relates to a stacked heat exchanger including a stack of a plurality of passage tubes through which a refrigerant flows, and a method for producing the stacked heat exchanger.

### BACKGROUND

A stacked heat exchanger has a plurality of passage tubes in a stacked arrangement. The plurality of passage tubes each has a projecting pipe that projects in the stacking direction of the passage tubes. The projecting pipes of the passage tubes adjacent to each other in the stacking direction are joined together so that a heat carrier can flow through the passage tubes.

### SUMMARY

According to at least one embodiment of the present disclosure, a stacked heat exchanger is for heat exchange between refrigerant and a heat exchange object that is disposed between a plurality of passage tubes which are stacked in a stacking direction for the refrigerant flowing through the plurality of passage tubes. The stacked heat exchanger includes: a first passage tube that is included in the plurality of passage tubes and extends in an extending direction intersecting the stacking direction; and a second passage tube that is included in the plurality of passage tubes and extends in the extending direction, the first passage tube facing the second passage tube in the stacking direction. The first passage tube has a first projecting pipe having a tubular shape. The first projecting pipe is adjacent to the heat exchange object in the extending direction and projects in the stacking direction. The second passage tube has a second projecting pipe having a tubular shape. The second projecting pipe is adjacent to the heat exchange object in the extending direction and projects in a direction opposite to the stacking direction.

The second projecting pipe has a fitted portion fitted into an inner side of the first projecting pipe, and the second projecting pipe is connected to the first projecting pipe so as to allow the refrigerant to flow through the first projecting pipe, The first projecting pipe has a joined portion having a tubular shape, and the joined portion is joined to an outer side of the fitted portion in a radial direction of the fitted portion.

The joined portion has an outer circumferential surface and an end of the first projecting pipe. The outer circumferential surface of the joined portion reaches the end by extending in the stacking direction to the end along an outer circumferential surface of the fitted portion.

### BRIEF DESCRIPTION OF DRAWINGS

FIG. 1 is a view illustrating a whole configuration of a stacked heat exchanger according to at least one embodiment.

FIG. 2 is a cross-sectional view illustrating a cross section of one-side tube portions of passage tubes of the at least one embodiment, that is, a cross-sectional view illustrating a cross section of area II of FIG. 1.

FIG. 3 is a detailed cross-sectional view in which area III of FIG. 2 is enlarged.

FIG. 4 is a view seen along arrow IV of FIG. 2.

FIG. 5 is a detailed view in which area V of FIG. 4 is enlarged.

FIG. 6 is a cross-sectional view taken along line VI-VI of FIG. 5.

FIG. 7 is a cross-sectional view taken along line VII-VII of FIG. 2.

FIG. 8 is a flowchart illustrating a method for producing a stacked heat exchanger of the at least one embodiment.

FIG. 9 is a cross-sectional view corresponding to FIG. 2 illustrating a cross section of area II of FIG. 1, and illustrating a state after assembling and before brazing of members of the stacked heat exchanger.

FIG. 10 is a cross-sectional view illustrating a cross section orthogonal to a central axis line of a fitted portion, and schematically illustrating a protrusion of the fitted portion and the vicinity of the protrusion after the completion of a second step and before the start of a third step of FIG. 8.

FIG. 11 is a cross-sectional view illustrating a virtual gap assumed in a first step of FIG. 8 in a cross section orthogonal to the central axis line of the fitted portion, and a view for explaining a method for geometrically determining the virtual gap.

FIG. 12 is a view illustrating a second other-side outer shell plate as a second member, which is prepared in the first step of FIG. 8, in a state before the start of the second step and is a cross-sectional view illustrating a cross section of a second projecting pipe and the vicinity thereof, which are extracted from the second other-side outer shell plate, using the same cross section as FIG. 9.

FIG. 13 is a view illustrating a first one-side outer shell plate as a first member, which is prepared in the first step of FIG. 8, in a state before the start of the second step and is a cross-sectional view illustrating a cross section of a first projecting pipe and the vicinity thereof, which are extracted from the first one-side outer shell plate, using the same cross section as FIG. 9.

FIG. 14 is a cross-sectional view illustrating a cross section of an area corresponding to area II of FIG. 1 in a stacked heat exchanger of a comparative example, and is a view corresponding to FIG. 2 of the at least one embodiment.

### DETAILED DESCRIPTION

A stacked heat exchanger according to a comparative example has a plurality of passage tubes in a stacked arrangement. The plurality of passage tubes each has a projecting pipe that projects in the stacking direction of the passage tubes. The projecting pipes of the passage tubes adjacent to each other in the stacking direction are joined together so that a heat carrier can flow through the passage tubes.

The projecting pipes of the stacked heat exchanger of the comparative example are joined together by brazing using a ring-shaped brazing wire while one of the projecting pipes is fitted into another one of the projecting pipes. Thus, in order to receive the brazing wire for the brazing, a part of an outer projecting pipe near an end, which is the other one of the projecting pipes, has a shape that increases in diameter in a direction toward the end. In short, the end of the outer projecting pipe has a flare shape.

In the stacked heat exchanger of the comparative example, the end part of the outer projecting pipe of the passage tube has the flare shape and thus is partially not brazed to an inner projecting pipe fitted to the outer projecting pipe.

Thus, in order to secure a sufficient brazed joint with the outer projecting pipe having such a shape, the projecting height of the outer projecting pipe needs to be higher. For example, the outer projecting pipe of the stacked heat exchanger can be assumed to be formed by pressing, and at the time of pressing, the drawing depth of the outer projecting pipe needs to be increased. Hence, difficulty in processing the part including the outer projecting pipe may increase. The inventor has found the above facts as a result of detailed study.

According to an aspect of the present disclosure, a stacked heat exchanger is for heat exchange between refrigerant and a heat exchange object that is disposed between a plurality of passage tubes which are stacked in a stacking direction for the refrigerant flowing through the plurality of passage tubes. The stacked heat exchanger includes: a first passage tube that is included in the plurality of passage tubes and extends in an extending direction intersecting the stacking direction; and a second passage tube that is included in the plurality of passage tubes and extends in the extending direction, the first passage tube facing the second passage tube in the stacking direction. The first passage tube has a first projecting pipe having a tubular shape. The first projecting pipe is adjacent to the heat exchange object in the extending direction and projects in the stacking direction. The second passage tube has a second projecting pipe having a tubular shape. The second projecting pipe is adjacent to the heat exchange object in the extending direction and projects in a direction opposite to the stacking direction. The second projecting pipe has a fitted portion fitted into an inner side of the first projecting pipe, and the second projecting pipe is connected to the first projecting pipe so as to allow the refrigerant to flow through the first projecting pipe, The first projecting pipe has a joined portion having a tubular shape, and the joined portion is joined to an outer side of the fitted portion in a radial direction of the fitted portion. The joined portion has an outer circumferential surface and an end of the first projecting pipe. The outer circumferential surface of the joined portion reaches the end by extending in the stacking direction to the end along an outer circumferential surface of the fitted portion.

As a result, the first projecting pipe corresponding to the outer projecting pipe can be joined to the second projecting pipe up to the end of the first projecting pipe. The projecting height of the first projecting pipe can be reduced accordingly. A joining method other than brazing using a ring-shaped brazing wire may be arbitrarily used for joining the first projecting pipe and the second projecting pipe.

According to another aspect of the present disclosure, a method is for producing a stacked heat exchanger. The stacked heat exchanger includes: a first passage tube for refrigerant flowing therethrough, the first passage tube extending in an extending direction; and a second passage tube for the refrigerant flowing therethrough, the first passage tube facing the second passage tube in a stacking direction intersecting the extending direction. The stacked heat exchanger performs heat exchange between the refrigerant and a heat exchange object disposed between the first passage tube and the second passage tube. The method includes: preparation of members, preparing a first member that forms a part of the first passage tube and preparing a second member that forms a part of the second passage tube; assembling of members, assembling the first member and the second member that have been prepared; and joining of members, brazing the first member and the second member that have been assembled. The first member is made of a laminated material having a core layer and a surface layer, the first member has a first projecting pipe having a tubular shape, and the first projecting pipe is adjacent to the heat exchange object in the extending direction and projects in the stacking direction in the stacked heat exchanger. The second member has a second projecting pipe having a tubular shape, and the second projecting pipe is adjacent to the heat exchange object in the extending direction and projects in a direction opposite to the stacking direction in the stacked heat exchanger. The surface layer of the first member is made of a brazing material, and the surface layer of the first projecting pipe is laminated on an inner side of the core layer in a radial direction of the first projecting pipe. In the preparation of members, the brazing material of the surface layer of the prepared first member contains a component that is higher in corrosion potential than aluminum. The assembling of members includes fitting the second projecting pipe into an inner side of the first projecting pipe. The joining of members includes brazing the first projecting pipe and the second projecting pipe by temporarily melting and then solidifying the brazing material of the surface layer.

The first member is made of the laminated material as described above. The second projecting pipe of the second member is then fitted into an inner side of the first projecting pipe of the first member, and thereafter the first projecting pipe and the second projecting pipe are brazed together. The first projecting pipe and the second projecting pipe can thus be brazed together without need for a ring-shaped brazing wire. Therefore, the first projecting pipe need not be provided with a shape for receiving the ring-shaped brazing wire. As a result, a producing method suitable for producing a stacked heat exchanger capable of reducing the projecting height of the first projecting pipe can be provided.

In the preparation of members, the brazing material of the surface layer of the prepared first member contains the component that is higher in corrosion potential than aluminum. The brazed joint brazed by the brazing material thus contains the component having the high corrosion potential. As a result, corrosion by the refrigerant at the brazed joint can be prevented.

In addition, according to further another aspect of the present disclosure, a method is for producing a stacked heat exchanger. The stacked heat exchanger includes: a first passage tube for refrigerant flowing therethrough, the first passage tube extending in an extending direction; and a second passage tube for the refrigerant flowing therethrough, the first passage tube facing the second passage tube in a stacking direction intersecting the extending direction. The stacked heat exchanger performs heat exchange between the refrigerant and a heat exchange object disposed between the first passage tube and the second passage tube. The method includes: preparation of members, preparing a first member that forms a part of the first passage tube and preparing a second member that forms a part of the second passage tube; assembling of members, assembling the first member and the second member that have been prepared; and joining of members, brazing the first member and the second member that have been assembled. The first member is made of a laminated material having a core layer and a surface layer, the first member has a first projecting pipe having a tubular shape, the first projecting pipe is adjacent to the heat exchange object in the extending direction and projects in the stacking direction in the stacked heat exchanger. The second member has a second projecting pipe having a tubular shape, the second projecting pipe is adjacent to the heat exchange object in the extending direction and projects in a direction opposite to the stacking direction in the stacked heat exchanger. The surface layer of the first member is made of a brazing material, and the surface layer of the first projecting pipe is laminated on an inner side of the core layer in a radial direction of the first projecting pipe. The second member is made of aluminum alloy containing a component that is higher in corrosion potential than aluminum. The assembling of members includes fitting the second projecting pipe into an inner side of the first projecting pipe such that the aluminum alloy forming the second projecting pipe of the second member and containing the component higher in corrosion potential than aluminum is in contact with the surface layer of the first member in the first projecting pipe. The joining of members includes brazing the first projecting pipe and the second projecting pipe by temporarily melting and then solidifying the brazing material of the surface layer.

The first projecting pipe and the second projecting pipe are brazed as described above. Therefore, similar to the method for producing a stacked heat exchanger according to the “another aspect of the present disclosure” described above, a producing method suitable for producing a stacked heat exchanger capable of reducing the projecting height of the first projecting pipe can be provided.

As described above, the second member is made of the aluminum alloy containing the component that is higher in corrosion potential than aluminum. The assembling of members includes fitting the second projecting pipe into the inner side of the first projecting pipe such that the aluminum alloy forming the second projecting pipe of the second member is in contact with the surface layer of the first member in the first projecting pipe. Therefore, when the brazing material of the surface layer of the first member is melted in the joining of members, some of the component having a high corrosion potential contained in the aluminum alloy of the second projecting pipe transfers to the brazing material being melted. Accordingly, the brazed joint between the first projecting pipe and the second projecting pipe becomes to contain the component having a high corrosion potential. As a result, corrosion by the refrigerant at the brazed joint can be prevented.

Embodiments will now be described with reference to the drawings. Parts that are identical or equivalent to each other in the following embodiments including other embodiments described below are assigned the same reference numerals in the drawings.

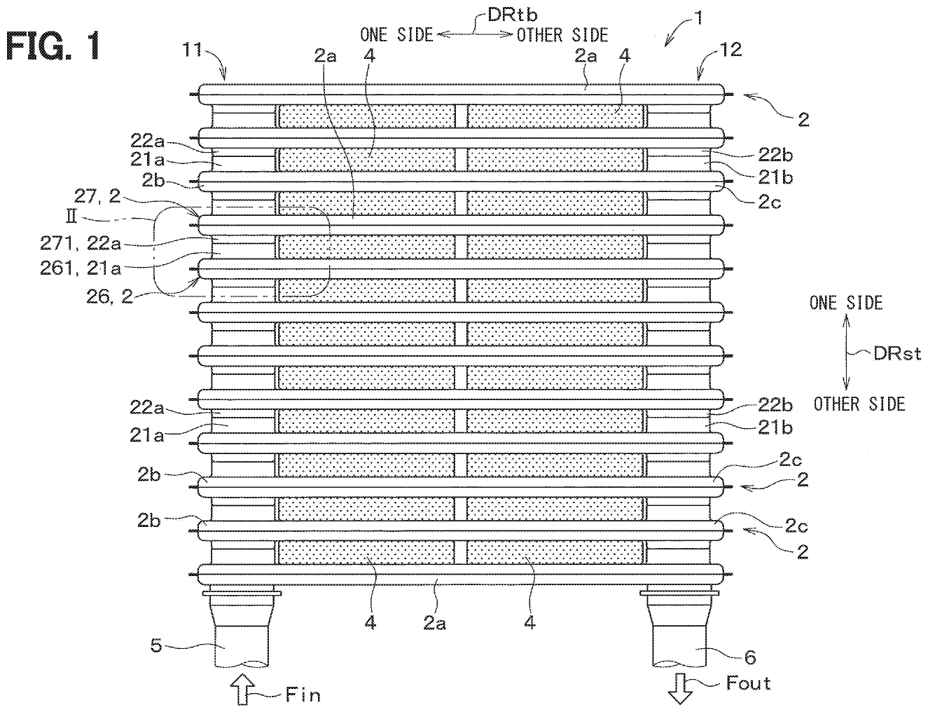

FIG. 1 is a view illustrating an overall configuration of a stacked heat exchanger 1 according to the present embodiment. The stacked heat exchanger 1 is a cooler that cools a heat exchange object by allowing heat exchange between a refrigerant circulating through the stacked heat exchanger 1 and the heat exchange object. Specifically, the heat exchange object, that is, an object to be cooled, is a plurality of electronic components 4 each formed in a plate shape and disposed between a plurality of passage tubes 2, and the stacked heat exchanger 1 cools each of the electronic components 4 from both sides thereof. The stacked heat exchanger 1 is applied to a cooling module that cools the electronic components 4.

As the refrigerant of the stacked heat exchanger 1, a fluid containing water is used. For example, water mixed with ethylene glycol antifreeze, that is, an aqueous solution as cooling water, is used as the refrigerant. A tube stacking direction DRst and a tube longitudinal direction DRtb in FIG. 1 as well as a tube width direction DRw in FIG. 4 described later are directions intersecting one another or, strictly speaking, directions orthogonal to one another.

The electronic component 4 as the heat exchange object is specifically formed in the shape of a flat rectangular parallelepiped. The electronic component 4 accommodates a power element or the like controlling large electric power as an element of a power converter that converts a direct current into an alternating current.

In the electronic component 4, for example, a power electrode extends from one long side outer peripheral surface of the component, and a control electrode extends from another long side outer peripheral surface of the component. Specifically, the electronic component 4 is a semiconductor module incorporating a semiconductor element such as an IGBT (that is, an insulated gate bipolar transistor) and a diode. The semiconductor module forms a part of a vehicle inverter.

As illustrated in FIG. 1, the stacked heat exchanger 1 includes the plurality of passage tubes 2. The passage tubes 2 are each formed as a refrigerant tube through which the refrigerant flows. The stacked heat exchanger 1 is formed by stacking the plurality of passage tubes 2 in the tube stacking direction DRst.

Each of the plurality of passage tubes 2 is formed to extend in the tube longitudinal direction DRtb as the extending direction of the passage tube 2. Moreover, each of the plurality of passage tubes 2 has a middle tube portion 2a, a one-side tube portion 2b, an other-side tube portion 2c, a pair of outer projecting pipes 21a and 21b each in the shape of a pipe (specifically, a circular pipe), and a pair of inner projecting pipes 22a and 22b each in the shape of a pipe (specifically, a circular pipe).

However, as illustrated in FIG. 1, the passage tube 2 located at one end in the tube stacking direction DRst among the plurality of passage tubes 2 does not have the pair of outer projecting pipes 21a and 21b. The passage tube 2 located at another end in the tube stacking direction DRst does not have the pair of inner projecting pipes 22a and 22b.

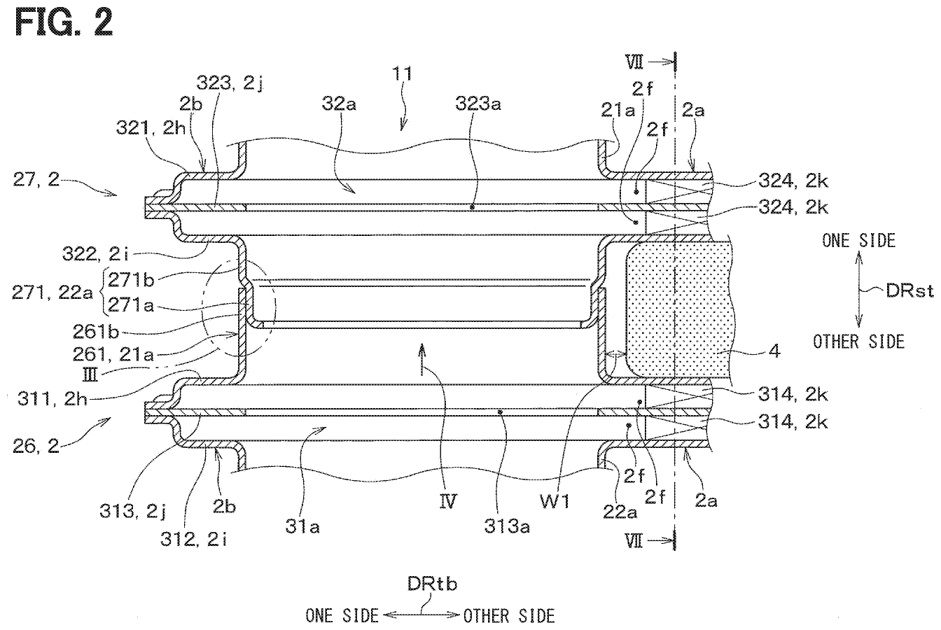

The middle tube portion 2a, the one-side tube portion 2b, and the other-side tube portion 2c are arranged side by side in the order of the one-side tube portion 2b, the middle tube portion 2a, and the other-side tube portion 2c from one side of the tube longitudinal direction DRtb. That is, the one-side tube portion 2b is formed to extend toward one side of the tube longitudinal direction DRtb from the middle tube portion 2a, and the other-side tube portion 2c is formed to extend toward the other side of the tube longitudinal direction DRtb from the middle tube portion 2a. The middle tube portion 2a, the one-side tube portion 2b, and the other-side tube portion 2c as a whole form a flat shape with the thickness in the direction of the tube stacking direction DRst. Moreover, as illustrated in FIGS. 1 and 2, the middle tube portion 2a is in contact with the electronic component 4 and includes a middle tube passage 2f formed inside the middle tube portion 2a to allow passage of the refrigerant between the one-side tube portion 2b and the other-side tube portion 2c.

One outer projecting pipe 21a of the pair of outer projecting pipes 21a and 21b projects toward one side of the tube stacking direction DRst from the one-side tube portion 2b. The one outer projecting pipe 21a is disposed at one side of the tube longitudinal direction DRtb relative to the electronic component 4.

The other outer projecting pipe 21b of the pair of outer projecting pipes 21a and 21b projects toward one side of the tube stacking direction DRst from the other-side tube portion 2c. The other outer projecting pipe 21b is disposed at the other side of the tube longitudinal direction DRtb relative to the electronic component 4.

One inner projecting pipe 22a of the pair of inner projecting pipes 22a and 22b projects toward the other side of the tube stacking direction DRst from the one-side tube portion 2b. The one inner projecting pipe 22a is disposed at one side of the tube longitudinal direction DRtb relative to the electronic component 4.

The other inner projecting pipe 22b of the pair of inner projecting pipes 22a and 22b projects toward the other side of the tube stacking direction DRst from the other-side tube portion 2c. The other inner projecting pipe 22b is disposed at the other side of the tube longitudinal direction DRtb relative to the electronic component 4.

Between the passage tubes 2 adjacent to each other, the one outer projecting pipe 21a and the one inner projecting pipe 22a are connected to each other to allow passage of the refrigerant therethrough. Such a connection allows a plurality of the one outer projecting pipes 21a, a plurality of the one inner projecting pipes 22a, and a plurality of the one-side tube portions 2b to be connected in the tube stacking direction DRst and form a supply header portion 11 that supplies the refrigerant to the middle tube passages 2f. One end of each of the plurality of middle tube portions 2a is thus connected to the supply header portion 11.

Moreover, between the passage tubes 2 adjacent to each other, the other outer projecting pipe 21b and the other inner projecting pipe 22b are connected to each other to allow passage of the refrigerant therethrough. Such a connection allows a plurality of the other outer projecting pipes 21b, a plurality of the other inner projecting pipes 22b, and a plurality of the other-side tube portions 2c to be connected in the tube stacking direction DRst and form a discharge header portion 12 that allows inflow of the refrigerant discharged from the middle tube passages 2f. Another end of each of the plurality of middle tube portions 2a is thus connected to the discharge header portion 12.

The middle tube portion 2a of the passage tube 2 is disposed to be in contact with one main surface of the electronic component 4 at one flat surface thereof, and in contact with another main surface of another electronic component 4 at another flat surface. That is, in the tube stacking direction DRst, the plurality of electronic components 4 and the plurality of middle tube portions 2a are alternately stacked. The middle tube portions 2a are further disposed at both ends in the tube stacking direction DRst of an assembly in which the plurality of electronic components 4 and the plurality of middle tube portions 2a are in the stacked arrangement. Moreover, the middle tube portion 2a of the passage tube 2 is pressed in the tube stacking direction DRst against each of the electronic components 4 in contact with the middle tube portion 2a. With such a stacked arrangement of the middle tube portions 2a of the passage tubes 2 and the electronic components 4, the middle tube portions 2a allow the refrigerant flowing through the middle tube passages 2f to release heat to the electronic components 4 and cool the plurality of electronic components 4 from both sides.

As illustrated in FIG. 1, a refrigerant introduction pipe 5 and a refrigerant discharge pipe 6 are connected to the one-side tube portion 2b and the other-side tube portion 2c, respectively, of the passage tube 2 that is located at an end on the other side of the tube stacking direction DRst among the plurality of passage tubes 2. For example, the refrigerant introduction pipe 5 is joined to the one-side tube portion 2b by brazing, and the refrigerant discharge pipe 6 is joined to the other-side tube portion 2c by brazing. The refrigerant thus flows into the supply header portion 11 from the outside of the stacked heat exchanger 1 via the refrigerant introduction pipe 5 as indicated by arrow Fin, and flows out of the discharge header portion 12 to the outside of the stacked heat exchanger 1 via the refrigerant discharge pipe 6 as indicated by arrow Fout.

Next, the detailed structure of the passage tubes 2 will be described with reference to FIG. 2. FIG. 2 is a view illustrating the passage tubes from the same angle as FIG. 1, and is a cross-sectional view of area II of FIG. 1 taken along a plane including the central axis line of the outer and inner projecting pipes 21a and 22a. FIG. 2 illustrates one of the plurality of passage tubes 2 included in the stacked heat exchanger 1 as a first passage tube 26. Another one of the plurality of passage tubes 2 disposed adjacent to the first passage tube 26 on one side of the tube stacking direction DRst is illustrated as a second passage tube 27. Among the plurality of passage tubes 2 stacked, the first passage tube 26 and the second passage tube 27 are not the passage tubes 2 located at the end on one or the other side of the tube stacking direction DRst, but are the passage tubes 2 disposed in the middle of the stack. Thus, the first passage tube 26 and the second passage tube 27 are the same component.

In the following description, the one outer projecting pipe 21a of the first passage tube 26 is also referred to as a first projecting pipe 261, and the one inner projecting pipe 22a of the second passage tube 27 is also referred to as a second projecting pipe 271.

As illustrated in FIG. 2, the second projecting pipe 271 is formed in the shape of a two-tier circular pipe with an end having a small diameter. Specifically, the second projecting pipe 271 has a fitted portion 271a including the end of the second projecting pipe 271, and a base portion 271b provided on one side in the tube stacking direction DRst with respect to the fitted portion 271a.

The base portion 271b is formed to have an outer diameter larger than an outer diameter of the fitted portion 271a. In other words, the fitted portion 271a is a reduced diameter portion whose diameter is smaller than that of the base portion 271b.

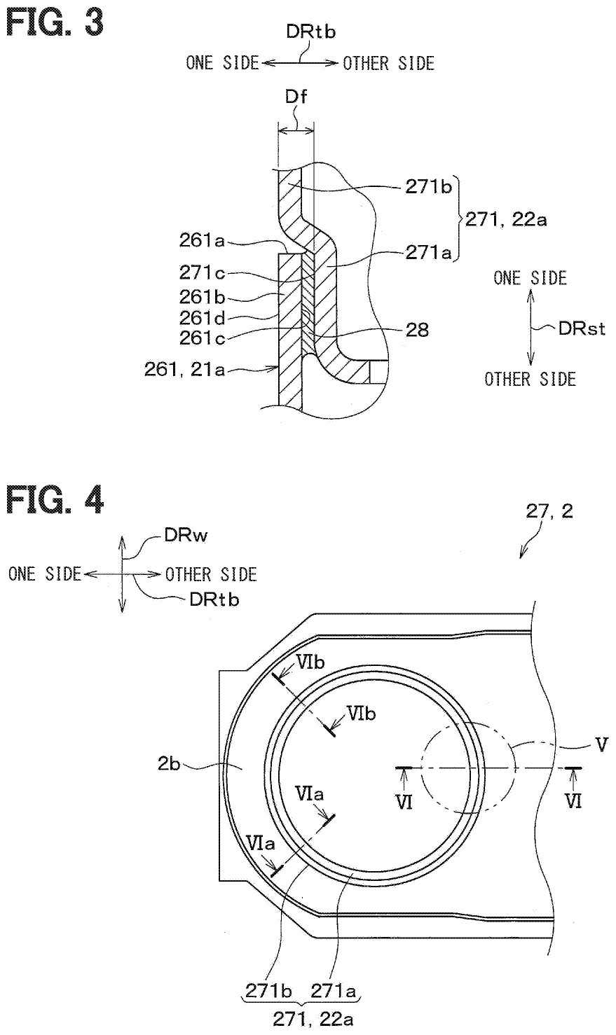

The fitted portion 271a of the second projecting pipe 271 is fitted inside the first projecting pipe 261. Specifically, as illustrated in FIGS. 2 and 3, the first projecting pipe 261 has a joined portion 261b of a tubular shape including an end 261a of the first projecting pipe 261. The end 261a of the first projecting pipe 261 is also the end of the joined portion 261b. The fitted portion 271a of the second projecting pipe 271 is fitted inside the joined portion 261b of the first projecting pipe 261.

Moreover, the joined portion 261b is joined to the fitted portion 271a on the radially outer side of the fitted portion 271a. In the present embodiment, the joined portion 261b is joined to the fitted portion 271a by brazing. Therefore, between the joined portion 261b and the fitted portion 271a in the radial direction of the first and second projecting pipes 261 and 271, a brazing material part 28 including a brazing material is formed to join the joined portion 261b and the fitted portion 271a together.

The joined portion 261b of the first projecting pipe 261 has an outer circumferential surface 261d which is an outer wall surface on the radially outer side of the joined portion 261b. The outer circumferential surface 261d is formed over the entire length of the joined portion 261b in the tube stacking direction DRst.

The first projecting pipe 261 of the present embodiment does not have a shape in which the end is open radially outward as the outer projecting pipe. That is, as illustrated in FIGS. 2 and 3, the first projecting pipe 261 extends in the tube stacking direction DRst up to the end 261a of the first projecting pipe 261 such that the outer diameter of the joined portion 261b does not change depending on the position in the tube stacking direction DRst. For the inner diameter of the joined portion 261b as well, the first projecting pipe 261 extends in the tube stacking direction DRst up to the end 261a of the first projecting pipe 261 such that the inner diameter of the joined portion 261b does not change depending on the position in the tube stacking direction DRst.

In other words, the outer circumferential surface 261d of the joined portion 261b of the first projecting pipe 261 extends in the tube stacking direction DRst up to the end 261a of the first projecting pipe 261 along an outer circumferential surface 271c of the fitted portion 271a, and reaches the end 261a. The “outer diameter of the joined portion 261b does not change” above has a practical meaning and indicates, for example, that the outer diameter of the joined portion 261b does not change to such an extent that brazing of the fitted portion 271a and the joined portion 261b is affected. The similar applies to the meaning of “the inner diameter of the joined portion 261b does not change”.

For example, the outer circumferential surface 261d of the joined portion 261b extends in the tube stacking direction DRst along the outer circumferential surface 271c of the fitted portion 271a up to the end 261a of the first projecting pipe 261 throughout the joined portion 261b. Specifically, an inner peripheral side surface 261c of the joined portion 261b faces the outer circumferential surface 271c of the fitted portion 271a in the radial direction of the fitted portion 271a. The inner peripheral side surface 261c of the joined portion 261b extends in the tube stacking direction DRst along the outer circumferential surface 271c of the fitted portion 271a up to the end 261a of the first projecting pipe 261 while facing the outer circumferential surface 271c.

The joined portion 261b of the first projecting pipe 261 has such a straight tubular shape, so that the brazing material part 28 reaches the end 261a of the first projecting pipe 261 in the tube stacking direction DRst. That is, the brazing of the joined portion 261b to the fitted portion 271a extends to the end 261a of the first projecting pipe 261 in the tube stacking direction DRst.

The inner diameter of the joined portion 261b at the end 261a of the first projecting pipe 261 is smaller than the outer diameter of the base portion 271b of the second projecting pipe 271.

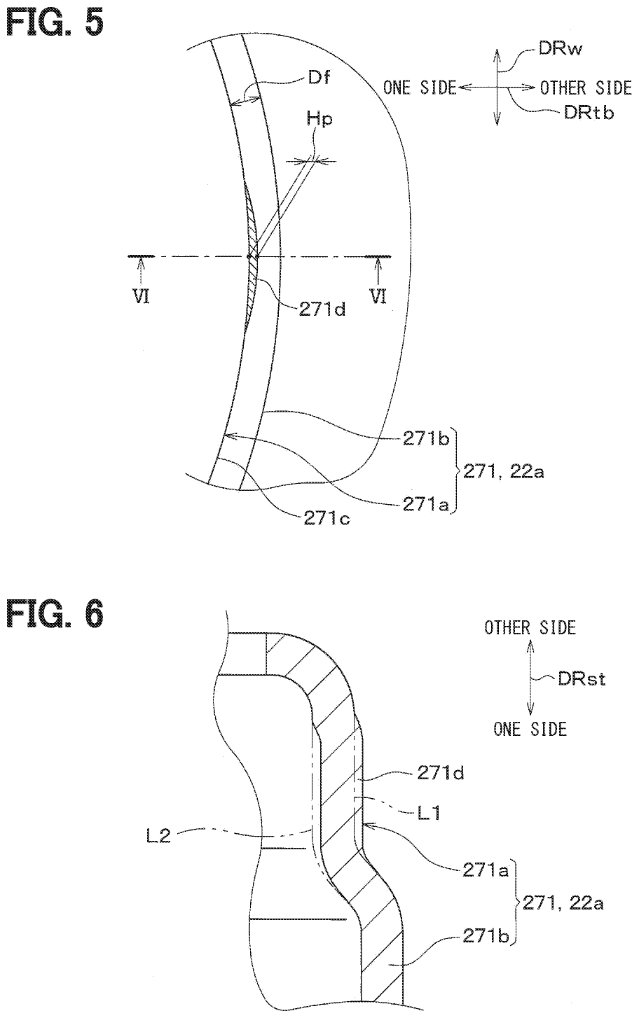

The second projecting pipe 271 has a circular tubular shape as illustrated in FIG. 4, but when viewed in detail, as illustrated in FIGS. 5 and 6, the fitted portion 271a of the second projecting pipe 271 has a protrusion 271d that protrudes outward in the radial direction of the fitted portion 271a. A protrusion height Hp of the protrusion 271d in the radial direction of the fitted portion 271a is smaller than a difference in level Df in the radial direction between the fitted portion 271a and the base portion 271b. The difference in level Df is illustrated in FIG. 3.

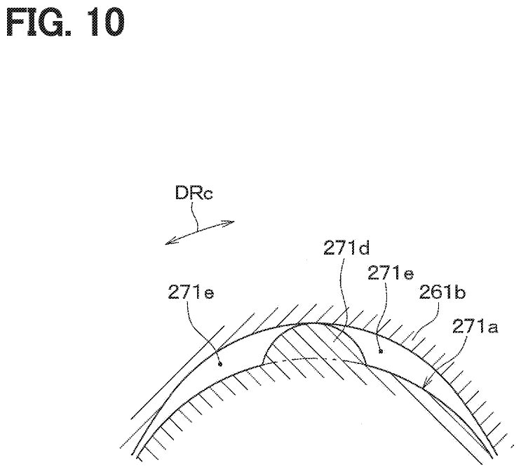

A plurality of the protrusions 271d included in the fitted portion 271a is equally spaced in the circumferential direction of the second projecting pipe 271. In the present embodiment, for example, three of the protrusions 271d are provided in the second projecting pipe 271 and are equally spaced from one another in the circumferential direction of the second projecting pipe 271. That is, the three protrusions 271d are disposed at 120-degree pitches in the circumferential direction of the second projecting pipe 271. Accordingly, the shape of the second projecting pipe 271 in a cross section taken along VIa-VIa and a cross section taken along VIb-VIb in FIG. 4 is similar to that in FIG. 6. In FIG. 5, the protrusion 271d is hatched for clear illustration thereof. In FIG. 6, two-dot dashed lines L1 and L2 represent the outline of a part of the fitted portion 271a in which the protrusion 271d is not provided. Moreover, as one can see from FIG. 4, for example, the circumferential direction of the second projecting pipe 271 above is the same as a circumferential direction DRc of the fitted portion 271a (see FIG. 10).

The joined portion 261b of the first projecting pipe 261 forms a clearance fit with the fitted portion 271a excluding the protrusion 271d and an interference fit with the fitted portion 271a including the protrusion 271d. Thus, in a fitted state in which the fitted portion 271a of the second projecting pipe 271 is fitted in the joined portion 261b of the first projecting pipe 261 as in FIG. 2, the protrusion 271d locally strongly presses the joined portion 261b outward in the radial direction of the fitted portion 271a. The fitted portion 271a can thus be reliably brought into contact with the joined portion 261b. Although the protrusion height Hp of the protrusion 271d illustrated in FIG. 5 decreases in the fitted state compared to the state before fitting, the protrusion 271d has a protruding shape protruding outward in the radial direction of the fitted portion 271a even in the fitted state.

Next, focusing on the configuration of members of the first passage tube 26 and the second passage tube 27, the passage tubes 26 and 27 are each formed by stacking a plurality of metal plates with high thermal conductivity and joining the plates by brazing. Specifically, as illustrated in FIG. 2, the first passage tube 26 has a pair of first outer shell plates 311 and 312, a first middle plate 313, and two first inner fins 314. Likewise, the second passage tube 27 has a pair of second outer shell plates 321 and 322, a second middle plate 323, and two second inner fins 324.

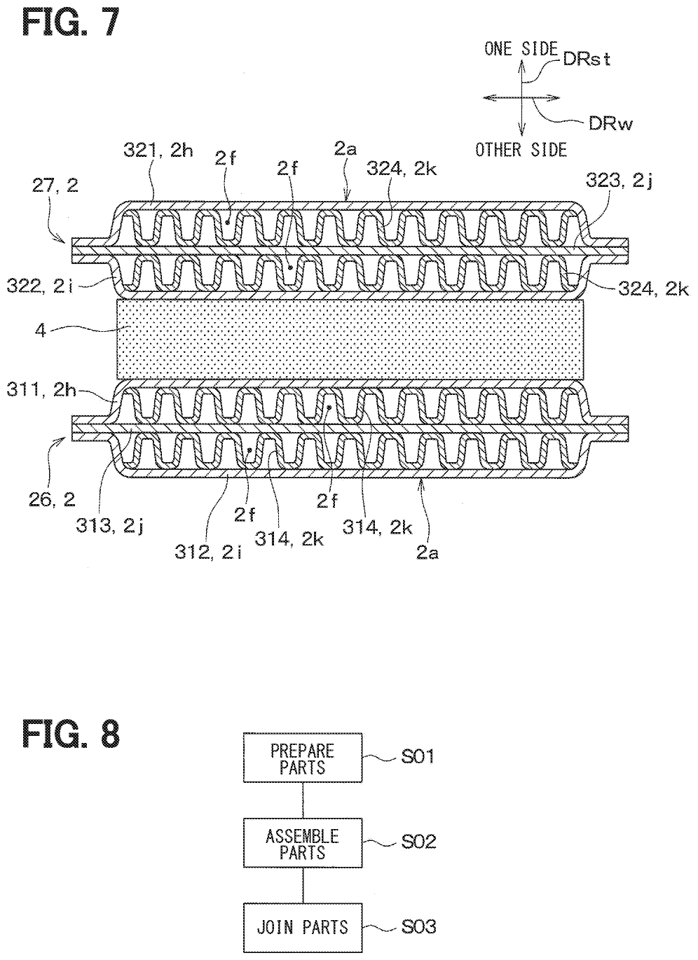

As illustrated in FIGS. 2 and 7, the pair of first outer shell plates 311 and 312 of the first passage tube 26 is a part forming the outer shell of the first passage tube 26. The pair of first outer shell plates 311 and 312 is disposed to be stacked in the tube stacking direction DRst. Then, an internal space 31a through which the refrigerant flows in the first passage tube 26 is formed between the pair of first outer shell plates 311 and 312. The internal space 31a of the first passage tube 26 includes the middle tube passage 2f of the first passage tube 26. The pair of second outer shell plates 321 and 322 of the second passage tube 27 is a part forming the outer shell of the second passage tube 27. The pair of second outer shell plates 321 and 322 is disposed to be stacked in the tube stacking direction DRst. Then, an internal space 32a through which the refrigerant flows in the second passage tube 27 is formed between the pair of second outer shell plates 321 and 322. The internal space 32a of the second passage tube 27 includes the middle tube passage 2f of the second passage tube 27.

In order to give the following description clearly, one of the pair of first outer shell plates 311 and 312 of the first passage tube 26 on one side of the tube stacking direction DRst is also referred to as a first one-side outer shell plate 311, and another one of the pair of first outer shell plates on the other side of the tube stacking direction is also referred to as a first other-side outer shell plate 312. Moreover, one of the pair of second outer shell plates 321 and 322 of the second passage tube 27 on one side of the tube stacking direction DRst is also referred to as a second one-side outer shell plate 321, and another one of the pair of second outer shell plates on the other side of the tube stacking direction is also referred to as a second other-side outer shell plate 322.

Since the first passage tube 26 and the second passage tube 27 are the same components, the first one-side outer shell plate 311 is the same component as the second one-side outer shell plate 321, and the first other-side outer shell plate 312 is the same component as the second other-side outer shell plate 322. The first middle plate 313 is the same component as the second middle plate 323, and the first inner fin 314 is the same component as the second inner fin 324. The pair of first outer shell plates 311 and 312 is a part included in the first passage tube 26 as a pair of outer shell plates 2h and 2i included in each of the plurality of passage tubes 2. The first middle plate 313 is a part included in the first passage tube 26 as a middle plate 2j included in each of the plurality of passage tubes 2. The first inner fin 314 is a part included in the first passage tube 26 as an inner fin 2k included in each of the plurality of passage tubes 2.

The pair of second outer shell plates 321 and 322 is a part included in the second passage tube 27 as the pair of outer shell plates 2h and 2i included in each of the plurality of passage tubes 2. The second middle plate 323 is a part included in the second passage tube 27 as the middle plate 2j included in each of the plurality of passage tubes 2. The second inner fin 324 is a part included in the second passage tube 27 as the inner fin 2k included in each of the plurality of passage tubes 2.

In the first passage tube 26, the first one-side outer shell plate 311 has a portion included in the middle tube portion 2a of the first passage tube 26, a portion included in the one-side tube portion 2b thereof, and a portion included in the other-side tube portion 2c thereof. The similar applies to each of the first other-side outer shell plate 312 and the first middle plate 313. The first inner fins 314 are included in the middle tube portion 2a of the first passage tube 26.

Moreover, the first one-side outer shell plate 311 has the pair of outer projecting pipes 21a and 21b, and the first other-side outer shell plate 312 has the pair of inner projecting pipes 22a and 22b. Thus, in the first one-side outer shell plate 311, for example, the first projecting pipe 261 which is the one outer projecting pipe 21a of the pair of outer projecting pipes projects toward one side in the tube stacking direction DRst.

In the second passage tube 27, as with the first passage tube 26, the second one-side outer shell plate 321 has a portion included in the middle tube portion 2a of the second passage tube 27, a portion included in the one-side tube portion 2b thereof, and a portion included in the other-side tube portion 2c thereof. The similar applies to each of the second other-side outer shell plate 322 and the second middle plate 323. The second inner fins 324 are included in the middle tube portion 2a of the second passage tube 27.

Moreover, the second one-side outer shell plate 321 has the pair of outer projecting pipes 21a and 21b, and the second other-side outer shell plate 322 has the pair of inner projecting pipes 22a and 22b. Thus, in the second other-side outer shell plate 322 illustrated in FIG. 2, for example, the second projecting pipe 271 which is the one inner projecting pipe 22a of the pair of inner projecting pipes projects toward the other side in the tube stacking direction DRst.

As illustrated in FIGS. 2 and 7, the first middle plate 313 in the first passage tube 26 is disposed between the pair of first outer shell plates 311 and 312 in the tube stacking direction DRst. The first middle plate 313 is joined to each of the pair of first outer shell plates 311 and 312. Specifically, the peripheral edges of the pair of first outer shell plates 311 and 312 and the peripheral edge of the first middle plate 313 are joined by brazing while being stacked in the tube stacking direction DRst.

The first middle plate 313 divides the internal space 31a of the first passage tube 26 in the tube stacking direction DRst.

Moreover, a through hole 313a passing through the first middle plate 313 in the tube stacking direction DRst is formed in each of a part included in the one-side tube portion 2b and a part included in the other-side tube portion 2c of the first passage tube 26. The first middle plate 313 thus does not obstruct the flow of the refrigerant in the tube stacking direction DRst through the supply header portion 11 and the discharge header portion 12.

Likewise, the second middle plate 323 in the second passage tube 27 is disposed between the pair of second outer shell plates 321 and 322 in the tube stacking direction DRst. The second middle plate 323 is joined to each of the pair of second outer shell plates 321 and 322. Specifically, the peripheral edges of the pair of second outer shell plates 321 and 322 and the peripheral edge of the second middle plate 323 are joined by brazing while being stacked in the tube stacking direction DRst.

The second middle plate 323 divides the internal space 32a of the second passage tube 27 in the tube stacking direction DRst.

Moreover, a through hole 323a passing through the second middle plate 323 in the tube stacking direction DRst is formed in each of a part included in the one-side tube portion 2b and a part included in the other-side tube portion 2c of the second passage tube 27. The second middle plate 323 thus does not obstruct the flow of the refrigerant in the tube stacking direction DRst through the supply header portion 11 and the discharge header portion 12.

Each of the first inner fins 314 is formed in a corrugated shape, for example, and promotes heat exchange between the refrigerant flowing through the middle tube passage 2f and the electronic component 4. The two first inner fins 314 are disposed between the first one-side outer shell plate 311 and the first middle plate 313, and between the first other-side outer shell plate 312 and the first middle plate 313 in the middle tube portion 2a of the first passage tube 26. That is, the two first inner fins 314 are each disposed in the middle tube passage 2f of the first passage tube 26 and are stacked in the tube stacking direction DRst with the first middle plate 313 interposed therebetween.

The first inner fin 314 between the first one-side outer shell plate 311 and the first middle plate 313 is brazed to the first one-side outer shell plate 311 and the first middle plate 313. The first inner fin 314 between the first other-side outer shell plate 312 and the first middle plate 313 is brazed to the first other-side outer shell plate 312 and the first middle plate 313.

The second inner fins 324 are provided in the middle tube portion 2a of the second passage tube 27 as with the first inner fins 314 described above.

The supply header portion 11 is formed by stacking the structure illustrated in FIG. 2 and the like described above in the tube stacking direction DRst, so that, in the supply header portion 11, other portions not illustrated in FIG. 2 are formed similarly to the structure illustrated in FIG. 2 and the like for each passage tube 2. The discharge header portion 12 is also formed similarly to the supply header portion 11.

The stacked heat exchanger 1 is configured as described above so that the refrigerant flows into the supply header portion 11 from the refrigerant introduction pipe 5 as indicated by arrow Fin in FIG. 1. The refrigerant having flowed into the supply header portion 11 flows through the supply header portion 11 toward one side of the tube stacking direction DRst and is distributed to the middle tube passage 2f of each of the plurality of middle tube portions 2a. The refrigerant being distributed flows through each middle tube passage 2f and is subjected to heat exchange with the electronic component 4. Then, the refrigerant flows into the discharge header portion 12 from the middle tube passage 2f. At the same time, the refrigerant flows toward the other side of the tube stacking direction DRst in the discharge header portion 12. The refrigerant in the discharge header portion 12 is discharged from the inside of the discharge header portion 12 to the refrigerant discharge pipe 6 as indicated by arrow Fout in FIG. 1.

Next, a method for producing the stacked heat exchanger 1 of the present embodiment will be described.

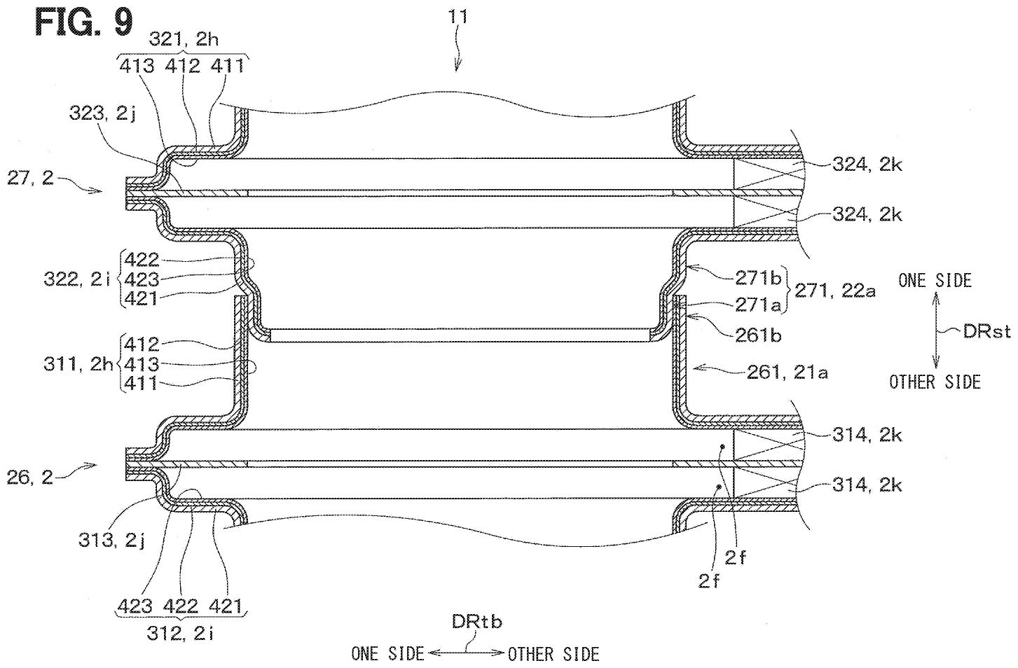

As illustrated in FIGS. 8 and 9, first, in a first step S01 corresponding to preparation of members, a plurality of members forming the stacked heat exchanger 1 is prepared. Specifically, the outer shell plates 2h and 2i, the middle plate 2j, and the inner fins 2k that form each passage tube 2, the refrigerant introduction pipe 5, and the refrigerant discharge pipe 6 are prepared. For example, regarding the first passage tube 26 among the plurality of passage tubes 2, the first one-side outer shell plate 311 as a first member, the first other-side outer shell plate 312, the first middle plate 313, and the first inner fins 314 are prepared. Regarding the second passage tube 27, the second one-side outer shell plate 321, the second other-side outer shell plate 322 as a second member, the second middle plate 323, and the second inner fins 324 are prepared.

The first one-side outer shell plate 311 and the second one-side outer shell plate 321 prepared in the first step S01 are each formed of a laminated material, specifically, a clad material, having a core layer 411, a sacrificial layer 412, and a surface layer 413. The surface layer 413, the sacrificial layer 412, and the core layer 411 are laminated in the order of the surface layer 413, the sacrificial layer 412, and the core layer 411 from the inner side of the passage tubes 26 and 27. Thus, in the first projecting pipe 261, for example, the surface layer 413 is laminated on the inner side in the radial direction of the first projecting pipe 261 with respect to the sacrificial layer 412, and the sacrificial layer 412 is laminated on the inner side in the radial direction of the first projecting pipe 261 with respect to the core layer 411.

The core layer 411 of each of the one-side outer shell plates 311 and 321 is made of aluminum-based aluminum alloy. The aluminum alloy of the core layer 411 contains a high potential component having a higher corrosion potential than aluminum as an additive component added to aluminum. In the present embodiment, the high potential component is Cu (that is, copper). The high potential component is a component added for the purpose of improving corrosion resistance, and is not an unavoidable impurity. Moreover, a high potential component contained in material other than the core layer 411 of the one-side outer shell plates 311 and 321 is not an unavoidable impurity, either.

The sacrificial layer 412 of each of the one-side outer shell plates 311 and 321 is made of a sacrificial corrosion material. The sacrificial corrosion material of the sacrificial layer 412 contains Zn (that is, zinc), for example. The sacrificial corrosion material corrodes preferentially over the core layer 411 to thus play a role of suppressing corrosion of the core layer 411.

The surface layer 413 of each of the one-side outer shell plates 311 and 321 is made of a brazing material suitable for brazing aluminum alloy. The brazing material is a joining medium for joining the parts. Moreover, the brazing material contains a high potential component having a higher corrosion potential than aluminum.

Similarly, the first other-side outer shell plate 312 and the second other-side outer shell plate 322 prepared in the first step S01 are each formed of a laminated material, specifically, a clad material, having a core layer 421, a sacrificial layer 422, and a surface layer 423. The surface layer 423, the sacrificial layer 422, and the core layer 421 are laminated in the order similar to that in the one-side outer shell plates 311 and 321 described above. Thus, in the second projecting pipe 271, for example, the surface layer 423 is laminated on the inner side in the radial direction of the second projecting pipe 271 with respect to the sacrificial layer 422, and the sacrificial layer 422 is laminated on the inner side in the radial direction of the second projecting pipe 271 with respect to the core layer 421.

The materials forming the layers 421, 422, and 423 of each of the other-side outer shell plates 312 and 322 are similar to that of the layers 411, 412, and 413 of each of the one-side outer shell plates 311 and 321 described above. That is, the core layer 421 of each of the other-side outer shell plates 312 and 322 is made of aluminum alloy. The aluminum alloy of the core layer 421 is composed primarily of aluminum and contains a high potential component having a higher corrosion potential than aluminum. The sacrificial layer 422 of each of the other-side outer shell plates 312 and 322 is made of a sacrificial corrosion material, which contains Zn (that is, zinc), for example. The surface layer 423 of each of the other-side outer shell plates 312 and 322 is made of a brazing material, which contains a high potential component having a higher corrosion potential than aluminum.

The first middle plate 313 and the second middle plate 323 prepared in the first step S01 are each formed as a single layer material made of aluminum alloy.

The aluminum alloy forming each of the middle plates 313 and 323 contains a high potential component having a higher corrosion potential than aluminum. In short, each of the middle plates 313 and 323 does not have a layer made of a brazing material and a layer made of a sacrificial corrosion material, but is formed of a core material made of aluminum alloy containing the high potential component.

The first inner fin 314 and the second inner fin 324 prepared in the first step S01 are each made of a clad material in which a brazing material is laminated on a core material made of aluminum alloy. For example, the first inner fin 314 may be a three-layer material in which the brazing material is provided on both sides of the core material, but the first inner fin of the present embodiment is formed as a two-layer material in which the brazing material is provided on the core material only on the side of the first middle plate 313. The similar applies to the second inner fin 324. The core material of each of the inner fins 314 and 324 does not contain the high potential component. After the first step S01, the process proceeds to a second step S02.

In the second step S02 corresponding to assembling of members, the plurality of members prepared in the first step S01 is assembled together and remains assembled. Specifically, the plurality of passage tubes 2 is assembled and stacked in the tube stacking direction DRst. When the passage tubes 2 are stacked, the pair of inner projecting pipes 22a and 22b is fitted into the pair of outer projecting pipes 21a and 21b, respectively.

For example, at one side of the first passage tube 26 and the second passage tube 27 in the tube longitudinal direction DRtb, the fitted portion 271a of the second projecting pipe 271 of the passage tube 27 is fitted inside the joined portion 261b of the first projecting pipe 261 of the passage tube 26. Specifically, the second projecting pipe 271 is fitted inside the first projecting pipe 261 such that the core layer 421 forming the second projecting pipe 271 is brought into contact with the surface layer 413 of the first projecting pipe 261. The similar applies to the other side of the first passage tube 26 and the second passage tube 27 in the tube longitudinal direction DRtb. The first one-side outer shell plate 311 and the second other-side outer shell plate 322 are assembled by these procedures.

In the fitting of the fitted portion 271a into the joined portion 261b described above, the fitted portion 271a is specifically press-fit to the joined portion 261b. This is because the fitted portion 271a is provided with the plurality of protrusions 271d (see FIGS. 5 and 6), and the protrusions 271d locally strongly press the joined portion 261b outward in the radial direction of the fitted portion 271a. In other words, before the fitting, the diameter of a circumscribed circle circumscribing the plurality of protrusions 271d is slightly larger than the inner diameter (that is, the diameter on the inner side) of the joined portion 261b.

Moreover, for the first passage tube 26, the pair of first outer shell plates 311 and 312, the first middle plate 313, and the first inner fins 314 are assembled. At this time, at the peripheral edge of the first middle plate 313, the pair of first outer shell plates 311 and 312 is stacked on one side and the other side of the tube stacking direction DRst with respect to the first middle plate 313 and is brought into contact therewith. That is, the aluminum alloy forming the first middle plate 313 and containing the high potential component is brought into contact with the surface layer 413 of the first one-side outer shell plate 311 and the surface layer 423 of the first other-side outer shell plate 312 at the brazed part. The similar applies to the second passage tube 27.

As described above, the fitted portion 271a is provided with the plurality of protrusions 271d (see FIGS. 5 and 6) to press-fit the fitted portion 271a into the joined portion 261b. Thus, after the completion of the second step S02 and before the start of a next third step S03, as illustrated in FIG. 10, a protrusion adjoining gap 271e is formed on both sides adjoining the protrusion 271d in the circumferential direction DRc of the fitted portion 271a (that is, the fitted portion circumferential direction DRc). The protrusion adjoining gap 271e needs to be filled with solidified brazing material after the completion of brazing in the next third step S03. The gap needs to be filled in order to airtightly join the first projecting pipe 261 and the second projecting pipe 271.

Accordingly, in the first step S01 of the present embodiment described above, a virtual gap CR corresponding to the protrusion adjoining gap 271e is assumed in advance on the basis of the dimensions of each of the joined portion 261b and the fitted portion 271a. The plurality of members prepared in the first step S01 is then selected such that the virtual gap CR is smaller than a predetermined size.

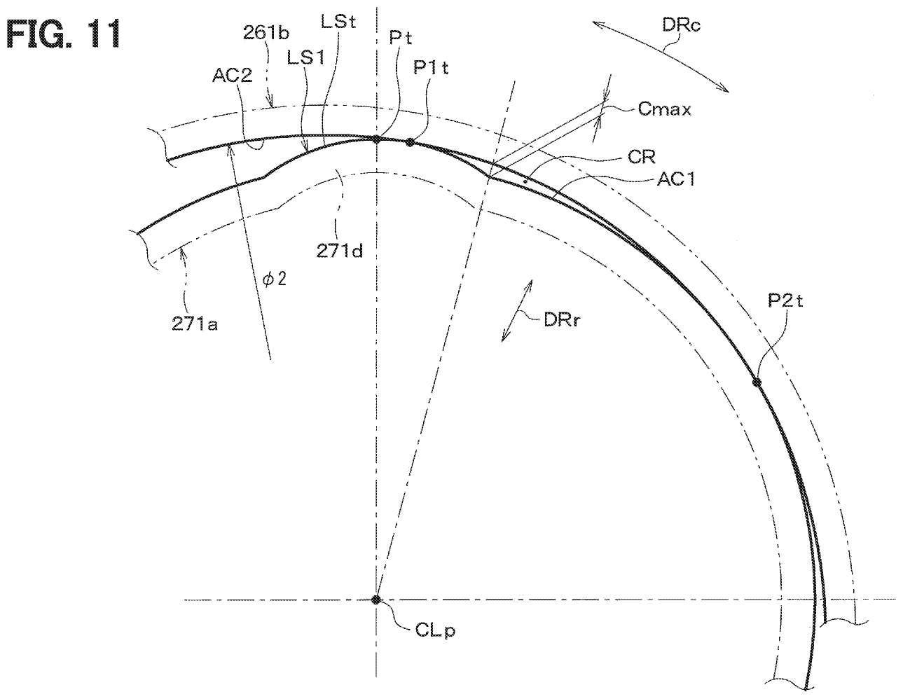

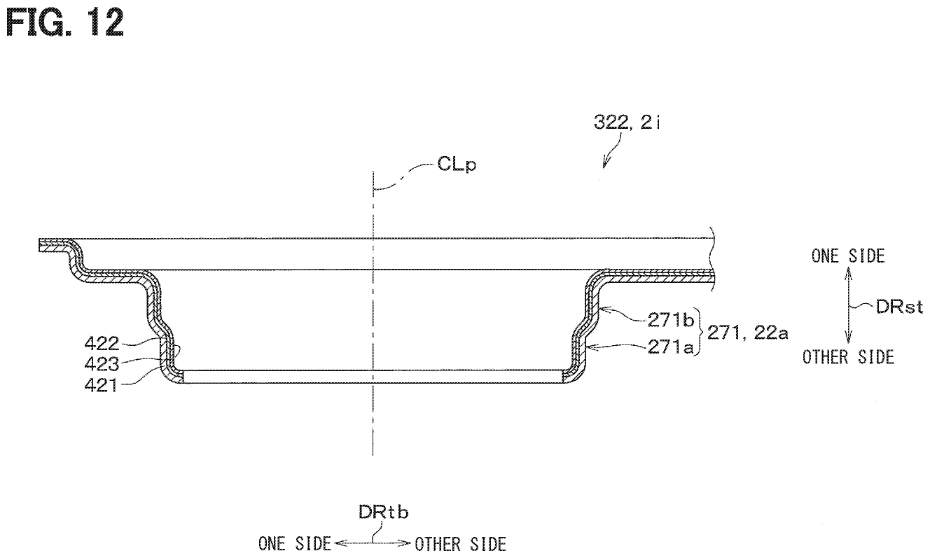

Specifically, in the first step 501, the virtual gap CR corresponding to the protrusion adjoining gap 271e is assumed in a cross section that is a section orthogonal to the central axis line CLp of the fitted portion 271a, as illustrated in FIGS. 11 and 12. FIG. 11 illustrates the cross section orthogonal to the central axis line CLp of the fitted portion 271a.

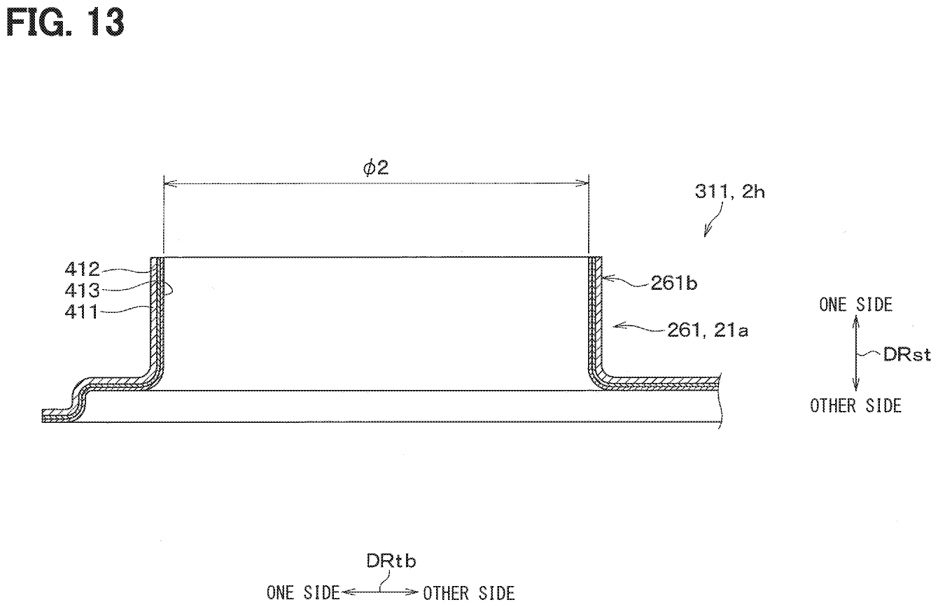

The virtual gap CR illustrated in the cross section of FIG. 11 is formed between a fitted portion outline LS1 indicating the outline on the radially outer side of the fitted portion 271a, and a joined portion arc AC2. The joined portion arc AC2 is a circular arc having the same diameter as an inner diameter φ2 of the joined portion 261b and curved outward in the radial direction of the fitted portion 271a, and is in contact with the fitted portion outline LS1 from the radially outer side of the fitted portion 271a. The inner diameter φ2 of the joined portion 261b for determining the joined portion arc AC2 is the dimension of the joined portion 261b in the first step S01, and is specifically the inner diameter of the surface layer 413 of the joined portion 261b as illustrated in FIG. 13.

Furthermore, as illustrated in FIG. 11, the fitted portion outline LS1 includes a protrusion outline LSt indicating the outline of the protrusion 271d, and a fitted portion outline arc AC1 connected to the protrusion outline LSt and centered on the central axis line CLp of the fitted portion 271a. The fitted portion outline arc AC1 is smaller in diameter than the joined portion arc AC2 by 0.1 mm. The fitted portion outline arc AC1 indicates the outline of a part of the fitted portion 271a where the protrusion 271d is not provided. The protrusion outline LSt is formed by an arc curved to convex outward in the radial direction of the fitted portion 271a.

In the cross section of FIG. 11, the joined portion arc AC2 is in contact with the fitted portion outline LS1 at two points being a first contact point P1t on the protrusion outline LSt and a second contact point P2t on the fitted portion outline arc AC1. The virtual gap CR is formed at a position shifted from a peak Pt of the protrusion outline LSt in the fitted portion circumferential direction DRc and between the first contact point P1t and the second contact point P2t. The peak Pt of the protrusion outline LSt is a point located on the outermost portion in the radial direction DRr of the fitted portion 271a on the protrusion outline LSt.

Thus in the first step S01, with the assumption of the virtual gap CR illustrated in the cross section of FIG. 11, a maximum gap width Cmax which is a maximum value Cmax of the width of the virtual gap CR in the radial direction DRr of the fitted portion 271a is determined geometrically. Then, parts with which the maximum gap width Cmax equals to a predetermined gap determination value or less are prepared as the first one-side outer shell plate 311 and the second other-side outer shell plate 322. In other words, the maximum gap width Cmax in FIG. 11 equals to the predetermined gap determination value or less on the basis of the dimensions of the joined portion 261b of the first one-side outer shell plate 311 and the dimensions of the fitted portion 271a of the second other-side outer shell plate 322 that are prepared in the first step S01. The gap determination value is specifically set to 0.07 mm in advance.

As described above, the virtual gap CR is the gap assumed in advance corresponding to the protrusion adjoining gap 271e of FIG. 10. The maximum gap width Cmax can thus be said to be an assumed value, which is assumed before the fitting of the joined portion 261b and the fitted portion 271a, for the maximum value of the width of the protrusion adjoining gap 271e in the radial direction DRr of the fitted portion 271a.

As illustrated in FIGS. 8 and 9, in a third step S03 corresponding to joining of members, the plurality of members assembled in the second step S02 is brazed. At this time, the brazing material is temporarily melted by heating and is solidified by subsequent cooling. The parts in contact with each other are thus brazed together.

Between the first and second projecting pipes 261 and 271, for example, the brazing material of the surface layer 413 of the first one-side outer shell plate 311 is temporarily melted and then solidified, so that the first projecting pipe 261 and the second projecting pipe 271 are brazed. Specifically, in the brazing of the first projecting pipe 261 and the second projecting pipe 271, the joined portion 261b of a cylindrical shape included in the first projecting pipe 261 is brazed to the fitted portion 271a of a cylindrical shape included in the second projecting pipe 271 and overlapping the joined portion 261b on the radially inner side thereof. At the same time, the brazing material part 28 of FIG. 3 is also formed. When the brazing material of the surface layer 413 is melted, the high potential component contained in the core layer 421 of the second projecting pipe 271 partly remains as is in the core layer 421 and is partly transferred to the brazing material melted.

As a result, some of the high potential component contained in the core layer 421 is contained in the brazing material part 28 after brazing. That is, the brazing material forming the brazing material part 28 contains the high potential component contained before the brazing and the high potential component transferred from the core layer 421 of the second projecting pipe 271 when the brazing material is melted.

Between the first one-side outer shell plate 311 and the first middle plate 313 of the first passage tube 26, the brazing material of the surface layer 413 of the first one-side outer shell plate 311 is temporarily melted and then solidified. The first one-side outer shell plate 311 and the first middle plate 313 are thus joined by brazing. At the same time, between the first other-side outer shell plate 312 and the first middle plate 313, the brazing material of the surface layer 423 of the first other-side outer shell plate 312 is temporarily melted and then solidified. The first other-side outer shell plate 312 and the first middle plate 313 are thus joined by brazing.

When the brazing material of each of the surface layers 413 and 423 is melted, the high potential component contained in the first middle plate 313 partly remains as is in the first middle plate 313 and is partly transferred to the brazing material melted. Thus, some of the high potential component contained in the first middle plate 313 is contained in the brazing material that joins the pair of first outer shell plates 311 and 312 and the first middle plate 313 after brazing.

The first inner fins 314 of the first passage tube 26 are brazed to the corresponding first outer shell plates 311 and 312 and the first middle plate 313 adjacent thereto. As for the second passage tube 27, the plates 321, 322, and 323 and the second inner fins 324 are brazed as with the first passage tube 26.

In the third step S03, the refrigerant introduction pipe 5 and the refrigerant discharge pipe 6 are also brazed to the passage tube 2 located at the end on the other side of the tube stacking direction DRst among the plurality of passage tubes 2.

As one may see, the brazing material is melted in the third step S03 so that after brazing when the third step S03 have been executed, the surface layer 413 of each of the one-side outer shell plates 311 and 321 is formed of a small amount of brazing material left unmelted. That is, the surface layer 413 after brazing is formed of a small amount of brazing material as compared to that before brazing. The similar applies to another part having the brazing material before brazing.

The stacked heat exchanger 1 is produced as described above and, as illustrated in FIG. 1, the electronic components 4 are interposed between the middle tube portions 2a of the plurality of passage tubes 2 in the stacked heat exchanger 1. In the stacked heat exchanger 1, the passage tubes 2 compress the electronic components 4 in the tube stacking direction DRst, and such a compressed state is maintained.

According to the present embodiment described above, as illustrated in FIGS. 2 and 3, the first projecting pipe 261 has the joined portion 261b of a tubular shape joined to the fitted portion 271a of the second projecting pipe 271 on the radially outer side of the fitted portion 271a. The outer circumferential surface 261d of the joined portion 261b extends in the tube stacking direction DRst along the outer circumferential surface 271c of the fitted portion 271a up to the end 261a of the first projecting pipe 261 and reaches the end 261a.

As a result, the first projecting pipe 261 can be joined to the second projecting pipe 271 all the way to the end 261a thereof. Accordingly, the width of joining is secured more easily in the tube stacking direction DRst as compared to a case where, for example, the joining of the first projecting pipe 261 to the second projecting pipe 271 does not extend to the end 261a. Specifically, in the present embodiment, the brazing of the joined portion 261b to the fitted portion 271a extends to the end 261a of the first projecting pipe 261 in the tube stacking direction DRst.

Therefore, the projecting height of the first projecting pipe 261 can be reduced. That is, the level of difficulty in processing the first projecting pipe 261, that is, the level of difficulty in processing the outer projecting pipe 21a, can be decreased while at the same time brazability can be improved in brazing the outer projecting pipes 21a and 21b and the inner projecting pipes 22a and 22b together.

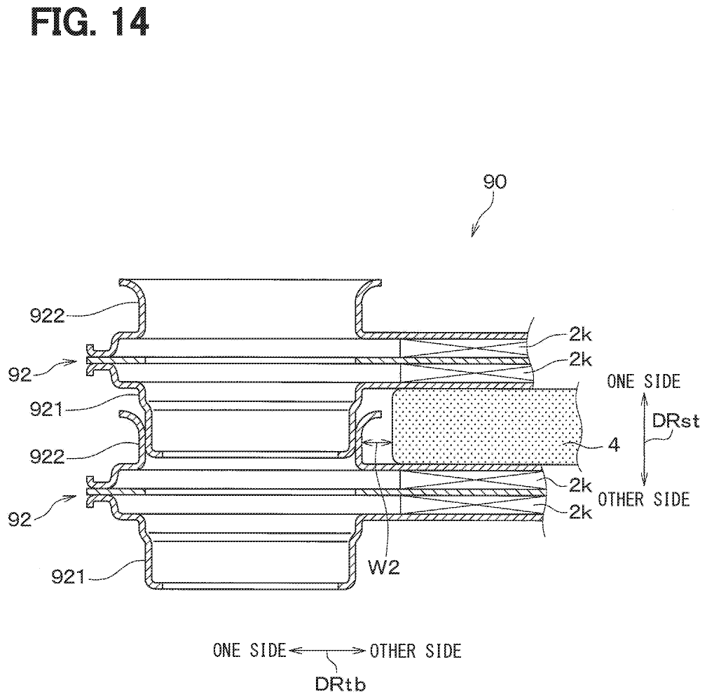

When a stacked heat exchanger 90 is assumed as a comparative example, the stacked heat exchanger 90 of the comparative example has a plurality of passage tubes 92 stacked similarly to the passage tubes 2 of the present embodiment, as illustrated in FIG. 14. Although an inner projecting pipe 921 included in the passage tube 92 of the comparative example is similar to that of the present embodiment, an outer projecting pipe 922 included in the passage tube 92 of the comparative example is different from that of the present embodiment and has a larger diameter toward the end.

Thus, an interval W2 in the tube longitudinal direction DRtb between the base end of the outer projecting pipe 922 and the electronic component 4 in the comparative example of FIG. 14 is larger than an interval W1 in the tube longitudinal direction DRtb between the base end of each of the outer projecting pipes 21a and 21b and the electronic component 4 in the present embodiment of FIG. 2. That is, compared to the comparative example of FIG. 14, the present embodiment can secure a larger space in the tube longitudinal direction DRtb in assembling the electronic component 4.

According to the present embodiment, in the stacked heat exchanger 1 after brazing, the brazing material that joins together the fitted portion 271a and the joined portion 261b illustrated in FIGS. 2 and 3 forms the brazing material part 28 and contains the high potential component with a higher corrosion potential than aluminum. Therefore, the corrosion resistance of the brazing material part 28, which is the joint portion between the first projecting pipe 261 and the second passage tube 27, can be improved by the high potential component.

For example, in the present embodiment, since the first projecting pipe 261 has the sacrificial layer 412 therein as illustrated in FIG. 9, it is assumed that when the brazing material of the surface layer 413 is melted, some of zinc as the sacrificial corrosion material is transferred to the brazing material and that the brazing material part 28 contains the zinc. On the other hand, the high potential component contained in the brazing material improves the corrosion resistance of the brazing material part 28 as described above, whereby corrosion of the brazing material part 28 due to the zinc, for example, can be prevented.

According to the present embodiment, between the pair of outer shell plates 2h and 2i of the passage tube 2 illustrated in FIGS. 2 and 9, the outer shell plate 2i on the other side in the tube stacking direction DRst is made of aluminum alloy containing the high potential component with a higher corrosion potential than aluminum. That is, the second projecting pipe 271 is made of the aluminum alloy containing the high potential component. Specifically, the core layer 421 of the second projecting pipe 271 is made of the aluminum alloy containing the high potential component.

Thus, when the brazing material of the surface layer 413 of the first projecting pipe 261 is melted in the third step S03 of FIG. 8, some of the high potential component contained in the core layer 421 of the second projecting pipe 271 is transferred to the brazing material melted. The corrosion resistance of the brazing material part 28 of FIG. 3 can thus be improved by the high potential component transferred to the brazing material.

The core layer 411 of the first projecting pipe 261 also contains the high potential component, which however is less likely to be transferred to the melted brazing material of the surface layer 413 of the first projecting pipe 261. This is because the sacrificial layer 412 is provided between the core layer 411 and the surface layer 413 of the first projecting pipe 261. Therefore, the core layer 421 of the second projecting pipe 271 containing the high potential component provides an advantage that the high potential component can be supplied to the melted brazing material for joining the two projecting pipes 261 and 271 even when the two projecting pipes 261 and 271 have the sacrificial layers 412 and 422.

The present embodiment described above illustrates an example where the high potential component is contained in both the aluminum alloy of the core layer 421 of the second projecting pipe 271 and the brazing material of the surface layer 413 of the first projecting pipe 261 illustrated in FIG. 9. However, if the corrosion resistance of the brazing material part 28 is sufficiently achieved for the joining of the two projecting pipes 261 and 271, for example, one of the core layer 421 of the second projecting pipe 271 and the surface layer 413 of the first projecting pipe 261 need not contain the high potential component.

According to the present embodiment, the first and second middle plates 313 and 323 illustrated in FIGS. 2 and 9 are each made of aluminum alloy containing the high potential component with a higher corrosion potential than aluminum.

Accordingly, when the brazing material of each of the surface layers 413 and 423 of the pair of first outer shell plates 311 and 312 is melted in the third step S03 of FIG. 8, the aluminum alloy containing the high potential component of the first middle plate 313 is in contact with the melted brazing material. Thus, when the brazing material of each of the surface layers 413 and 423 is melted in the third step S03, some of the high potential component contained in the first middle plate 313 is transferred to each of the melted brazing material.

As a result, the corrosion resistance of the brazed joint between the first middle plate 313 and the pair of first outer shell plates 311 and 312 can be improved by the high potential component transferred to the brazing material. The similar applies to the brazed joint between the second middle plate 323 and the pair of second outer shell plates 321 and 322. After brazing, the core material of each of the first and second middle plates 313 and 323 is in contact with the brazing material joining the middle plates 313 and 323 to the corresponding outer shell plates 311, 312, 321, and 322. That is, the brazing material used for joining is in contact with the aluminum alloy that forms the core material of the middle plates 313 and 323 and contains the high potential component.

The core layers 411 and 421 of the outer shell plates 311, 312, 321, and 322 also contain the high potential components, but the sacrificial layers 412 and 422 are provided between the core layers 411 and 421 and the surface layers 413 and 423. As a result, the high potential components contained in the core layers 411 and 421 of the outer shell plates 311, 312, 321, and 322 are less likely to be transferred to the brazing material of the surface layers 413 and 423 melted in the joining between the outer shell plates 311, 312, 321, and 322 and the middle plates 313 and 323. Therefore, the first and second middle plates 313 and 323 containing the high potential components provide an advantage that the high potential components can be supplied to the melted brazing material even when the outer shell plates 311, 312, 321, and 322 have the sacrificial layers 412 and 422.

The present embodiment described above illustrates an example where the high potential component is contained in both the aluminum alloy of the middle plates 313 and 323 and the brazing material of the surface layers 413 and 423 of the outer shell plates 311, 312, 321, and 322 illustrated in FIG. 9.

However, if the corrosion resistance of the brazed joint is sufficiently achieved for the joining of the middle plates 313 and 323 and the outer shell plates 311, 312, 321, and 322, for example, the following may be adopted. That is, the high potential component need not be contained in one of the aluminum alloy of the middle plates 313 and 323 and the brazing material of the surface layers 413 and 423 of the outer shell plates 311, 312, 321, and 322.

According to the present embodiment, as illustrated in FIGS. 5 and 6, the fitted portion 271a of the second projecting pipe 271 has the protrusions 271d that protrude outward in the radial direction of the fitted portion 271a. The protrusions 271d locally strongly press the joined portion 261b of the first projecting pipe 261 outward in the radial direction of the fitted portion 271a. Thus, if the fitted portion 271a is pressed against the joined portion 261b over the entire circumference with no protrusion 271d provided, the fitting load is likely to be excessive at the time of assembling but, in the present embodiment, the protrusions 271d locally press the joined portion 261b so that the fitting load can be reduced. While reducing the fitting load in such a manner, the first projecting pipe 261 and the second projecting pipe 271 can be reliably brought into contact with each other.

According to the present embodiment, as illustrated in FIGS. 3 and 9, the first one-side outer shell plate 311 as the first member is formed of the laminated material including the core layer 411, the sacrificial layer 412, and the surface layer 413 including the brazing material. Then, the second projecting pipe 271 of the second other-side outer shell plate 322 as the second member is fitted inside the first projecting pipe 261 of the first one-side outer shell plate 311, and thereafter the first projecting pipe 261 and the second projecting pipe 271 are brazed together.

Thus, the first projecting pipe 261 and the second projecting pipe 271 can be brazed together without the need for the ring-shaped brazing wire. Moreover, the first projecting pipe 261 does not need to be provided with a shape for receiving the ring-shaped brazing wire so that the projecting height of the first projecting pipe 261 can be reduced. The number of parts can also be reduced by eliminating the ring-shaped brazing wire, whereby the second step S02 can be simplified, that is, the assembling step can be simplified.

If the ring-shaped brazing wire is required, for example, the inner projecting pipes 22a and 22b are first disposed in the orientation to project upward in the fitting of the projecting pipes 21a, 21b, 22a, and 22b in the above assembling step. The ring-shaped brazing wire is then fitted to the radially outer side of the upward inner projecting pipes 22a and 22b. After that, the outer projecting pipes 21a and 21b are fitted to the inner projecting pipes 22a and 22b. The assembling step thus has restrictions on the order of assembly and the orientation of the parts when the ring-shaped brazing wire is required, whereas the present embodiment has an advantage that there is no such restriction.

According to the present embodiment, as illustrated in FIGS. 8 and 9, the first one-side outer shell plate 311 as the first member prepared in the first step S01 contains the high potential component having a higher corrosion potential than aluminum in the brazing material of the surface layer 413. The high potential component is thus contained in the brazed joint formed by the brazing material. As a result, corrosion by the refrigerant at the brazed joint can be prevented.

According to the present embodiment, the core layer 421 of the second other-side outer shell plate 322 as the second member is made of aluminum alloy containing the high potential component with a higher corrosion potential than aluminum. The second step S02 of FIG. 8 includes fitting the second projecting pipe 271 inside the first projecting pipe 261 such that the core layer 421 forming the second projecting pipe 271 of the second other-side outer shell plate 322 is brought into contact with the surface layer 413 of the first projecting pipe 261. Thus, when the brazing material of the surface layer 413 of the first projecting pipe 261 is melted in the third step S03 of FIG. 8, some of the high potential component contained in the core layer 421 of the second projecting pipe 271 is transferred to the brazing material melted. The high potential component is thus contained in the brazing material part 28 in FIG. 3. As a result, corrosion by the refrigerant at the brazing material part 28 can be prevented.

According to the present embodiment, in the first step S01, the virtual gap CR in the cross section of FIG. 11 is assumed and the maximum gap width Cmax which is the maximum value Cmax of the width of the assumed virtual gap CR in the radial direction DRr of the fitted portion 271a is geometrically determined. Then, the parts with which the maximum gap width Cmax equals to 0.07 mm or less are prepared as the first one-side outer shell plate 311 and the second other-side outer shell plate 322.

As a result of an experiment conducted by the inventor, with “Cmax=0.040 mm”, the protrusion adjoining gap 271e of FIG. 10 was completely filled with the solidified brazing material after the completion of brazing in the third step S03. On the other hand, with “Cmax=0.072 mm”, the protrusion adjoining gap 271e of FIG. 10 was not completely filled with the solidified brazing material but had a small space left unfilled after the completion of brazing in the third step S03. Such a space can cause leakage of the refrigerant through the space.

Thus, by setting “Cmax≤0.07 mm” as described above, the first projecting pipe 261 and the second projecting pipe 271 can be airtightly joined to sufficiently prevent the leakage of the refrigerant through the boundary between the first projecting pipe 261 and the second projecting pipe 271.

As illustrated in FIG. 9, the first one-side outer shell plate 311 has three layers of materials including the core layer 411, the sacrificial layer 412, and the surface layer 413 made of the brazing material. The size limit of the protrusion adjoining gap 271e (see FIG. 10) that can be filled with the amount of brazing material that can be disposed upon securing productivity and corrosion resistance of such materials is the size in which the maximum value of the width of the protrusion adjoining gap 271e in the radial direction DRr of the fitted portion 271a equals to 0.07 mm. From this point of view as well, it is appropriate to set the maximum gap width Cmax in FIG. 11 to 0.07 mm or less. This is because the maximum gap width Cmax is the assumed value for the maximum value of the width of the protrusion adjoining gap 271e assumed before the fitting of the joined portion 261b and the fitted portion 271a.

According to the present embodiment, the maximum gap width Cmax in FIG. 11 is the value obtained on the basis of the dimensions of the joined portion 261b of the first one-side outer shell plate 311 and the dimensions of the fitted portion 271a of the second other-side outer shell plate 322 that are prepared in the first step 501. Therefore, without actually fitting the joined portion 261b and the fitted portion 271a in the second step S02 of FIG. 8, the leakage of the refrigerant through the boundary between the first projecting pipe 261 and the second projecting pipe 271 can be prevented in advance.

In the above embodiment, as illustrated in FIGS. 4 and 5, the second projecting pipe 271 includes three of the protrusions 271d, the number of which however is not limited and may be one.

One may also think of a case where no protrusion 271d is provided on the fitted portion 271a of the second projecting pipe 271 but, preferably, a plurality of the protrusions 271d is provided and equally spaced in the fitted portion circumferential direction DRc. In this case, even when four or more of the protrusions 271d are equally spaced, for example, one need not change the setting that the maximum gap width Cmax in FIG. 11 is to be 0.07 mm or less. This is because the maximum value of the width of the protrusion adjoining gap 271e (see FIG. 10) in the radial direction DRr of the fitted portion 271a when the joined portion 261b and the fitted portion 271a are actually fitted tends to decrease with the number of the protrusions 271d increasing. The smaller the maximum value of the width of the protrusion adjoining gap 271e becomes, the more easily the protrusion adjoining gap 271e is filled with the solidified brazing material in the third step S03 (see FIG. 8).

In the above embodiment, the plurality of members of each of the passage tubes 26 and 27 illustrated in FIG. 2 is joined to one another by brazing, but can be joined by another joining method other than brazing.

In the above embodiment, the high potential component contained in the core layers 411 and 421 and the brazing material of the outer shell plates 311, 312, 321, and 322 illustrated in FIG. 9 is Cu, but is not limited thereto. For example, the high potential component may be Cu, Ti, Ni, At, Ag, or a mixture thereof. In short, the high potential component may be at least any of Cu, Ti, Ni, At, and Ag.

In the above embodiment, the first middle plate 313 and the second middle plate 323 prepared in the first step S01 of FIG. 8 are each formed as the single layer material made of aluminum alloy as illustrated in FIG. 9, which is only an example. For example, the middle plates 313 and 323 may each be formed of a clad material in which a brazing material is laminated on a core material made of aluminum alloy.

In the above embodiment, as illustrated in FIG. 1, the electronic component 4 is sandwiched by the passage tubes 2 of the stacked heat exchanger 1, whereby the refrigerant in the passage tubes 2 can exchange heat with the electronic component 4. In this regard, the electronic component 4 may be disposed in direct contact with the passage tubes 2, or, as needed, a ceramic dielectric plate, thermal conductive grease, or the like may be interposed between the electronic component 4 and the passage tubes 2.

In the above embodiment, the stacked heat exchanger 1 is an apparatus for cooling the electronic component 4 as the heat exchange object, but the heat exchange object need not be the electronic component 4. For example, the heat exchange object may be a mechanical structure that is not energized. The stacked heat exchanger 1 may also be a heater equipped with a function of heating the heat exchange object.

In the above embodiment, the heat exchange object of the stacked heat exchanger 1 is the electronic component 4, that is, a solid, but the heat exchange object may be a gas or liquid.

In the above embodiment, as illustrated in FIG. 1, two of the electronic components 4 are disposed in each space between the passage tubes 2, but one or three or more of the electronic components 4 may be disposed in each space between the passage tubes 2.

In the above embodiment, each of the passage tubes 2 has the inner fins 2k as illustrated in FIG. 2, but there can be the passage tube 2 having no inner fin 2k.

In the above embodiment, each of the passage tubes 2 has the middle plate 2j as illustrated in FIG. 2, but there can be the passage tube 2 having no middle plate 2j.

In the above embodiment, as illustrated in FIG. 2, a corner R is formed at the base end which is the base portion of the first projecting pipe 261. The range of brazing between the joined portion 261b of the first projecting pipe 261 and the fitted portion 271a of the second projecting pipe 271 does not extend to an area of the corner R where the corner R is formed at the base end of the first projecting pipe 261 in the tube stacking direction DRst. Such a structure is only an example, and the range of brazing may extend to the area of the corner R. In that case, however, the area of the corner R is not included in the joined portion 261b. This is because the joined portion 261b is the portion formed such that the inner diameter and the outer diameter thereof do not change depending on the position in the tube stacking direction DRst. Also, at the base end of the first projecting pipe 261, the corner R is always formed in the manufacturing process of forming the first projecting pipe 261.

The present disclosure is not limited to the above embodiment but can be modified in various ways for implementation. Moreover, it goes without saying that the components included in the above embodiment are not necessarily required unless specified as being required, regarded as being clearly required in principle, or the like.

The numerical value such as the number, the numerical value, the quantity, the range, or the like of a component mentioned in the above embodiment is not limited to a specific number unless specified as being required, clearly limited to such a specific number in principle, or the like. The material, the shape, the positional relationship, and the like of a component or the like mentioned in the above embodiment are not limited to those being mentioned unless otherwise specified, limited to specific material, shape, positional relationship, and the like in principle, or the like.

What is claimed is:

1. A stacked heat exchanger for heat exchange between refrigerant and a heat exchange object that is disposed between a plurality of passage tubes which are stacked in a stacking direction for the refrigerant flowing through the plurality of passage tubes, the stacked heat exchanger comprising:
a first passage tube that is included in the plurality of passage tubes and extends in an extending direction intersecting the stacking direction; and
a second passage tube that is included in the plurality of passage tubes and extends in the extending direction, the first passage tube facing the second passage tube in the stacking direction, wherein
the first passage tube has a first projecting pipe having a tubular shape, the first projecting pipe being adjacent to the heat exchange object in the extending direction and projecting in the stacking direction,
the second passage tube has a second projecting pipe having a tubular shape, the second projecting pipe being adjacent to the heat exchange object in the extending direction and projecting in a direction opposite to the stacking direction,
the second projecting pipe has a fitted portion fitted into an inner side of the first projecting pipe, and the second projecting pipe is connected to the first projecting pipe so as to allow the refrigerant to flow through the first projecting pipe,
the first projecting pipe has a joined portion having a tubular shape, the joined portion being joined to an outer side of the fitted portion in a radial direction of the fitted portion,
the joined portion has an outer circumferential surface and an end of the first projecting pipe,
the outer circumferential surface of the joined portion reaches the end by extending in the stacking direction to the end along an outer circumferential surface of the fitted portion,
the first passage tube has a pair of outer shell plates that is stacked in the stacking direction and forms an outer shell of the first passage tube, and a middle plate that divides an internal space which is between the pair of outer shell plates and allows the refrigerant to flow therein, and
the middle plate is joined to each of the pair of outer shell plates and is made of aluminum alloy containing a component that is higher in corrosion potential than aluminum.

2. The stacked heat exchanger according to claim 1, wherein
the joined portion is joined to the fitted portion by brazing, and
the brazed joint between the joined portion and the fitted portion extends to the end of the first projecting pipe in the stacking direction.

3. The stacked heat exchanger according to claim 1, wherein the joined portion extends in the stacking direction to the end of the first projecting pipe without change in outer diameter of the joined portion.

4. The stacked heat exchanger according to claim 1, wherein
the fitted portion has a protrusion protruding outward in the radial direction of the fitted portion, and
the protrusion presses the joined portion outward in the radial direction of the fitted portion.

5. The stacked heat exchanger according to claim 1, wherein
the second projecting pipe has a base portion provided adjacent to the fitted portion in the stacking direction, and
the base portion has an outer diameter larger than an outer diameter of the fitted portion.

6. The stacked heat exchanger according to claim 1, wherein
the joined portion is joined to the fitted portion by brazing, and
a brazing material joining the fitted portion and the joined portion to each other contains the component that is higher in corrosion potential than aluminum.

7. The stacked heat exchanger according to claim 1, wherein the component higher in corrosion potential than aluminum is at least one of Cu, Ti, Ni, At, and Ag.

8. A method for producing a stacked heat exchanger including a plurality of passage tubes stacked in a stacking direction, the method comprising:
preparing a first member that forms a part of a first passage tube, the first member including a first projecting pipe having a tubular shape protruding from the first passage tube, the first projecting pipe having a surface layer on an inner side of the first projecting pipe in a radial direction of the first projecting pipe, the surface layer being made of a brazing material containing a component that is higher in corrosion potential than aluminum;
preparing a second member that forms a part of a second passage tube, the second member including a second projecting pipe having a tubular shape protruding from the second passage tube;
assembling the first member and the second member such that the second projecting pipe is inserted into the inner side of the first projecting pipe in the stacking direction, and the first and second projecting pipes are located adjacent to a heat exchange object interposed between the first and second passage tubes; and
brazing the first member and the second member to each other by temporarily melting and then solidifying the brazing material of the surface layer, wherein
the first passage tube includes a pair of outer shell plates that is stacked in the stacking direction and forms an outer shell of the first passage tube, and a middle plate that is joined to each of the pair of outer shell plates and divides an internal space which is between the pair of outer shell plates and allows the refrigerant flows therein,
the middle plate is made of aluminum alloy containing a component that is higher in corrosion potential than aluminum,
the first member is one of the pair of outer shell plates that faces outward in the stacking direction,
the assembling includes making the aluminum alloy of the middle plate contact the surface layer of the first member, and
the brazing includes brazing the first member and the middle plate to each other by temporarily melting and then solidifying the brazing material of the surface layer.

9. A method for producing a stacked heat exchanger including a plurality of passage tubes stacked in a stacking direction, the method comprising:
preparing a first member that forms a part of a first passage tube, the first member including a first projecting pipe having a tubular shape protruding from the first passage tube, the first projecting pipe having a surface layer on an inner side of the first projecting pipe in a radial direction of the first projecting pipe, the surface layer being made of a brazing material;
preparing a second member that forms a part of a second passage tube, the second member including a second projecting pipe having a tubular shape protruding from the second passage tube, the second member being made of aluminum alloy containing a component that is higher in corrosion potential than aluminum;
assembling the first member and the second member such that the second projecting pipe is inserted into the inner side of the first projecting pipe in the stacking direction, the aluminum alloy is in contact with the surface layer of the first member in the first projecting pipe, and the first and second projecting pipes are located adjacent to a heat exchange object interposed between the first and second passage tubes; and
brazing the first member and the second member to each other by temporarily melting and then solidifying the brazing material of the surface layer, wherein
the first passage tube includes a pair of outer shell plates that is stacked in the stacking direction and forms an outer shell of the first passage tube, and a middle plate that is joined to each of the pair of outer shell plates and divides an internal space which is between the pair of outer shell plates and allows the refrigerant flows therein,
the middle plate is made of aluminum alloy containing a component that is higher in corrosion potential than aluminum,
the first member is one of the pair of outer shell plates that faces outward in the stacking direction,
the assembling includes making the aluminum alloy of the middle plate contact the surface layer of the first member, and
the brazing includes brazing the first member and the middle plate to each other by temporarily melting and then solidifying the brazing material of the surface layer.

10. A method for producing a stacked heat exchanger including a plurality of passage tubes stacked in a stacking direction, the method comprising:
preparing a first member that forms a part of a first passage tube, the first member including a first projecting pipe having a tubular shape protruding from the first passage tube, the first projecting pipe having a surface layer on an inner side of the first projecting pipe in a radial direction of the first projecting pipe, the surface layer being made of a brazing material containing a component that is higher in corrosion potential than aluminum;
preparing a second member that forms a part of a second passage tube, the second member including a second projecting pipe having a tubular shape protruding from the second passage tube;
assembling the first member and the second member such that the second projecting pipe is inserted into the inner side of the first projecting pipe in the stacking direction, and the first and second projecting pipes are located adjacent to a heat exchange object interposed between the first and second passage tubes; and
brazing the first member and the second member to each other by temporarily melting and then solidifying the brazing material of the surface layer, wherein
the brazing includes brazing a joined portion of the first projecting pipe having a cylindrical shape to a fitted portion of the second projecting pipe having a cylindrical shape, the fitted portion being overlapped with an inner side of the joined portion in a radial direction of the fitted portion,
the fitted portion of the second member has a protrusion protruding outward in the radial direction of the fitted portion,
the assembling includes making the protrusion to press the joined portion outward in the radial direction of the fitted portion,
the second member has a structure in which a maximum value of a width of a virtual gap in the radial direction of the fitted portion is less than or equal to 0.07 mm,
the virtual gap is defined as a gap formed between a fitted portion outline and a joined portion arc in a cross section orthogonal to a central axis line of the fitted portion,
the fitted portion outline indicates a radially outer shape of the fitted portion,
the joined portion arc has the same diameter as an inner diameter of the joined portion, is curved to be convex outward in the radial direction of the fitted portion, and is in contact with the fitted portion outline from outside of the fitted portion in the radial direction,
the fitted portion outline includes a protrusion outline that indicates an outer shape of the protrusion having a peak, and the fitted portion outline includes a fitted portion outline arc that is connected to the protrusion outline, centered on the central axis line, and 0.1 millimeter smaller in diameter than the joined portion arc, and
in the cross section, the joined portion arc is in contact with the fitted portion outline at two points that are a contact point on the protrusion outline and a contact point on the fitted portion outline arc, and the virtual gap is formed at a position shifted from the peak of the protrusion outline in a circumferential direction of the fitted portion.

11. A method for producing a stacked heat exchanger including a plurality of passage tubes stacked in a stacking direction, the method comprising:
preparing a first member that forms a part of a first passage tube, the first member including a first projecting pipe having a tubular shape protruding from the first passage tube, the first projecting pipe having a surface layer on an inner side of the first projecting pipe in a radial direction of the first projecting pipe, the surface layer being made of a brazing material;
preparing a second member that forms a part of a second passage tube, the second member including a second projecting pipe having a tubular shape protruding from the second passage tube, the second member being made of aluminum alloy containing a component that is higher in corrosion potential than aluminum;
assembling the first member and the second member such that the second projecting pipe is inserted into the inner side of the first projecting pipe in the stacking direction, the aluminum alloy is in contact with the surface layer of the first member in the first projecting pipe, and the first and second projecting pipes are located adjacent to a heat exchange object interposed between the first and second passage tubes; and
brazing the first member and the second member to each other by temporarily melting and then solidifying the brazing material of the surface layer, wherein
the brazing includes brazing a joined portion of the first projecting pipe having a cylindrical shape to a fitted portion of the second projecting pipe having a cylindrical shape, the fitted portion being overlapped with an inner side of the joined portion in a radial direction of the fitted portion,
the fitted portion of the second member has a protrusion protruding outward in the radial direction of the fitted portion,
the assembling includes making the protrusion to press the joined portion outward in the radial direction of the fitted portion,
the second member has a structure in which a maximum value of a width of a virtual gap in the radial direction of the fitted portion is less than or equal to 0.07 mm,
the virtual gap is defined as a gap formed between a fitted portion outline and a joined portion arc in a cross section orthogonal to a central axis line of the fitted portion,
the fitted portion outline indicates a radially outer shape of the fitted portion,
the joined portion arc has the same diameter as an inner diameter of the joined portion, is curved to be convex outward in the radial direction of the fitted portion, and is in contact with the fitted portion outline from outside of the fitted portion in the radial direction,
the fitted portion outline includes a protrusion outline that indicates an outer shape of the protrusion having a peak, and the fitted portion outline includes a fitted portion outline arc that is connected to the protrusion outline, centered on the central axis line, and 0.1 millimeter smaller in diameter than the joined portion arc, and
in the cross section, the joined portion arc is in contact with the fitted portion outline at two points that are a contact point on the protrusion outline and a contact point on the fitted portion outline arc, and the virtual gap is formed at a position shifted from the peak of the protrusion outline in a circumferential direction of the fitted portion.

12. The method for producing a stacked heat exchanger, according to claim 8, wherein
the brazing includes brazing a joined portion of the first projecting pipe having a cylindrical shape to a fitted portion of the second projecting pipe having a cylindrical shape, the fitted portion being overlapped with an inner side of the joined portion in a radial direction of the fitted portion,
the fitted portion of the second member has a protrusion protruding outward in the radial direction of the fitted portion,
the assembling includes making the protrusion to press the joined portion outward in the radial direction of the fitted portion,
the second member has a structure in which a maximum value of a width of a virtual gap in the radial direction of the fitted portion is less than or equal to 0.07 mm,
the virtual gap is defined as a gap formed between a fitted portion outline and a joined portion arc in a cross section orthogonal to a central axis line of the fitted portion,
the fitted portion outline indicates a radially outer shape of the fitted portion,
the joined portion arc has the same diameter as an inner diameter of the joined portion, is curved to be convex outward in the radial direction of the fitted portion, and is in contact with the fitted portion outline from outside of the fitted portion in the radial direction,
the fitted portion outline includes a protrusion outline that indicates an outer shape of the protrusion having a peak, and the fitted portion outline includes a fitted portion outline arc that is connected to the protrusion outline, centered on the central axis line, and 0.1 millimeter smaller in diameter than the joined portion arc, and
in the cross section, the joined portion arc is in contact with the fitted portion outline at two points that are a contact point on the protrusion outline and a contact point on the fitted portion outline arc, and the virtual gap is formed at a position shifted from the peak of the protrusion outline in a circumferential direction of the fitted portion.
